(19) United States
(12) Patent Application Publication
(10) Pub. No.: US 2009/0243737 A1
(43) Pub. Date: Oct. 1, 2009

(54) MEMS oscillator

(75) Inventor: Yasushi Igarashi, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/320,875

(22) Filed: Feb. 6, 2009

(30) Foreign Application Priority Data
Mar. 25, 2008 (JP) 2008-077477

(51) Int. Cl. H03B 5/30

(52) U.S. Cl. 331/116 M

(57) ABSTRACT

A discharge electrode is provided on the opposite side of a fixed electrode with a beam portion being sandwiched therebetween. When the frequency of the MEMS oscillator is regulated by increasing the mass of a vibration element, the vibration element is used as a positive electrode and the discharge electrode as a negative electrode, and a direct current voltage is applied until an arc discharge occurs. When an arc discharge occurs between the vibration element and discharge electrode, an inert gas is ionized to become positive ions to collide against the discharge electrode to sputter or evaporate the material of the discharge electrode. A portion of discharged material from the discharge electrode adheres to the vibration element, therefore, the mass of the vibration element is increased to reduce a resonance frequency of the MEMS oscillator.

### CROSS-REFERENCE TO RELATED APPLICATION

This application claims priority under 35 USC 119 from Japanese Patent Application No. 2008-077477, the disclosure of which is incorporated by reference herein.

### BACKGROUND OF THE INVENTION

1. Field of the Invention

The present invention relates to a MEMS oscillator having a MEMS structure.

2. Description of Related Art

In Japanese National Phase Publication No. 2003-532320, a frequency regulation method of MEMS oscillators is described. More specifically, Japanese National Phase Publication No. 2003-532320 discloses a method by which plural MEMS oscillators whose frequencies are shifted are produced and a MEMS oscillator having a desired frequency is selected from the plural MEMS oscillators.

Further, Document 1: Design Wave Magazine, “Chapter 3: Internal Structure and Manufacturing Method of Crystal Resonators”, February 2007 issue, pp. 112-116, describes a frequency regulation method for crystal resonators. More specifically, a method of adjusting the frequency to the order of ppm by a method of performing vacuum deposition of an electrode material or by shaving off the electrode material by ion etching is disclosed.

However, according to a conventional frequency regulation method of MEMS oscillators as described, for example, in Japanese Patent Application National Publication No. 2003-532320, a considerable number of MEMS oscillators need to be formed and selected therefrom in order to adjust the frequency to a target frequency to the order of ppm and thus, there is a problem that the installation area of MEMS oscillators increases accordingly.

If, on the other hand, the frequency regulation method of crystal resonators as described, for example, in Document 1 is applied to MEMS oscillators, it is difficult to adjust individual MEMS oscillators in a wafer state and the MEMS oscillators need to be assembled into each chip before being vacuum-evaporated in a vacuum device and, therefore, there is a problem of increased costs.

### SUMMARY OF THE INVENTION

In consideration of the above facts, a subject of the present invention is to provide a MEMS oscillator capable of easily regulating the frequency.

A MEMS oscillator in a first aspect of the invention includes:

a vibration element disposed in opposition to a fixed electrode provided on a substrate; and

a discharge portion provided adjacent to the vibration element.

According to the above configuration, if a predetermined voltage is applied to the fixed electrode and the vibration element, an electrostatic force is generated between the fixed electrode and the vibration element, thereby the vibration element being vibrated.

On the other hand, a discharge portion is provided adjacent to the vibration element. If, for example, the frequency of the vibration element needs to be regulated to a desired frequency, discharge is effected by the discharge portion. The mass of the material constituting the vibration element is changed by evaporation caused by the discharge. Alternatively, the mass of the vibration element is changed by adhering to the vibration element a material that has been evaporated from the discharge portion.

By effecting a discharge by the discharge portion to change the mass of the vibration element in these ways, the frequency of the MEMS oscillator may be easily regulated.

In a second aspect of the invention, the vibration element and the discharge portion, of the first aspect, are disposed inside a sealed oscillation chamber and an inert gas is contained in the oscillation chamber.

According to the above configuration, an inert gas is contained in the oscillation chamber. When a discharge is caused by the discharge portion, the inert gas is ionized to become positive ions. The positive ions collide against one object used as a negative electrode and the one object is evaporated by the collision before being adhered to another object.

The mass of the vibration element may be reduced by evaporating the material constituting the vibration element by using, for example, the discharge portion as a positive electrode and the vibration element as a negative electrode. Conversely, the mass of the vibration element may be increased by making the material evaporated from the discharge portion adhere to the vibration element by using, for example, the discharge portion as a negative electrode and the vibration element as a positive electrode.

By containing an inert gas in the oscillation chamber in this manner, the mass of the vibration element may be changed effectively.

In a third aspect of the invention, the inert gas of the second aspect is at least one of helium, neon, argon, krypton, or xenon.

According to the above configuration, by ionizing one of helium, neon, argon, krypton, and xenon into positive ions, the positive ions collide against one object used as a negative electrode. The mass of the vibration element may thereby be effectively changed.

In a fourth aspect of the invention, a material of the vibration element and a material of the discharge portion, of one of the first through third aspects, are identical or comprise a common material.

For example, by using the discharge portion as a negative electrode and the vibration element as a positive electrode, positive ions generated by a discharge collide against the discharge portion used as a negative electrode to evaporate the material constituting the discharge portion. Then, the evaporated material adheres to the vibration element. Here, the material of the vibration element and that of the discharge portion are the same or a material common to both is contained. Thus, the evaporated material may be easily adhered to the vibration element to change the mass of the vibration element.

In a fifth aspect of the invention, the discharge portion of one of the first through fourth aspects comprises a single discharge electrode.

According to the above configuration, the discharge portion has one discharge electrode. The mass of the vibration element may be changed by applying a fixed voltage to the discharge electrode and vibration element to cause a discharge.

In a sixth aspect of the invention, the discharge portion of one of the first through fourth aspects comprises a pair of discharge electrodes.

According to the above configuration, the mass of the vibration element may be changed by using one discharge electrode as a negative electrode and the other electrode as a positive electrode to cause a discharge.

According to the invention, a MEMS oscillator capable of easily regulating the frequency may be provided.

### BRIEF DESCRIPTION OF THE DRAWINGS

Preferred exemplary embodiments of the present invention will be described in detail based on the following figures, wherein:

FIG. 1 is a perspective view showing a MEMS oscillator according to a first exemplary embodiment of the invention;

FIG. 2 is a plan view showing the MEMS oscillator according to the first exemplary embodiment of the invention;

FIG. 3 is a sectional view showing a semiconductor package provided with the MEMS oscillator according to the first exemplary embodiment of the invention;

FIG. 4 is a perspective view showing the MEMS oscillator according to a second exemplary embodiment of the invention;

FIG. 5 is a plan view showing the MEMS oscillator according to the second exemplary embodiment of the invention;

FIG. 6 is a perspective view showing the MEMS oscillator according to a third exemplary embodiment of the invention;

FIG. 7 is a sectional view showing the semiconductor package provided with the MEMS oscillator according to the third exemplary embodiment of the invention;

FIG. 8 is a perspective view showing the MEMS oscillator according to a fourth exemplary embodiment of the invention;

FIG. 9 is a perspective view showing the MEMS oscillator according to a fifth exemplary embodiment of the invention; and

FIG. 10 is a perspective view showing the MEMS oscillator according to a sixth exemplary embodiment of the invention.

### DETAILED DESCRIPTION OF THE INVENTION

### First Exemplary Embodiment

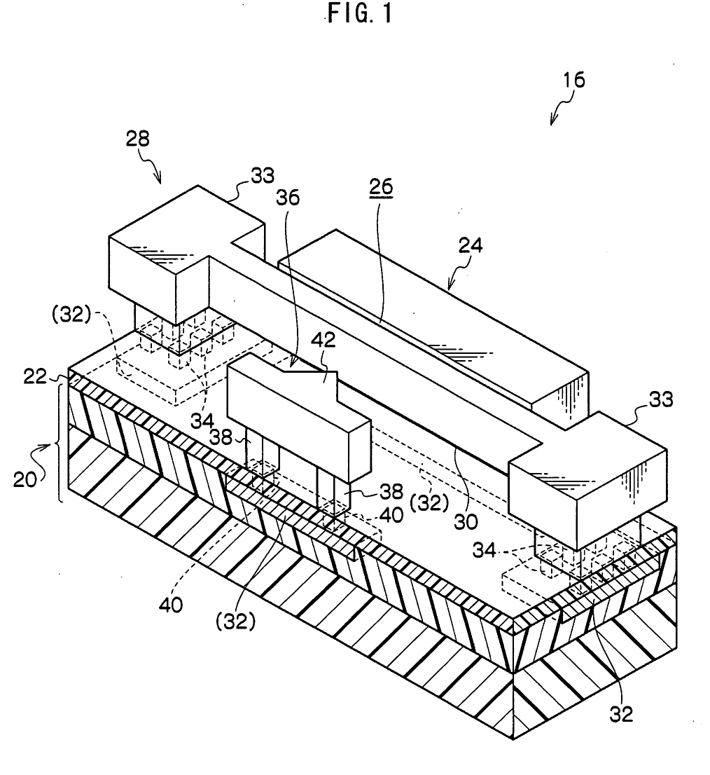

A semiconductor package in which an example of the MEMS oscillator according to the first exemplary embodiment of the present invention will be described by referring to FIG. 1 to FIG. 3.

(Constitution)

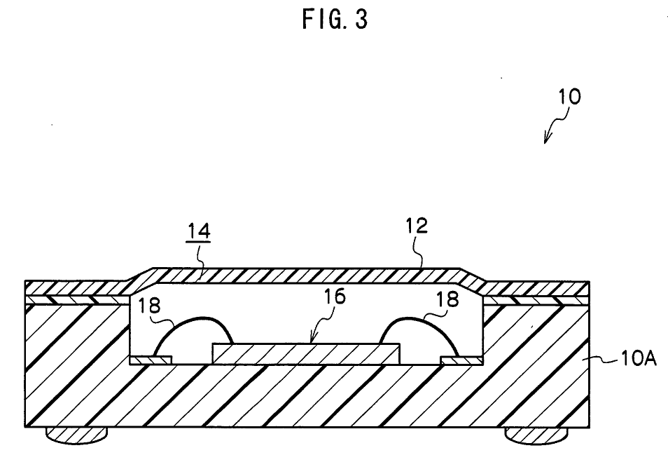

As shown in FIG. 3, an oscillation chamber 14 partitioned from the outside by being covered with a plate-shaped sealing cap 12 is provided inside a semiconductor package 10.

An approximate vacuum is maintained in the oscillation chamber 14 and a MEMS oscillator 16 having a MEMS structure is disposed inside the oscillation chamber 14. The MEMS oscillator 16 is electrically connected to a main body 10A by bonding wires 18.

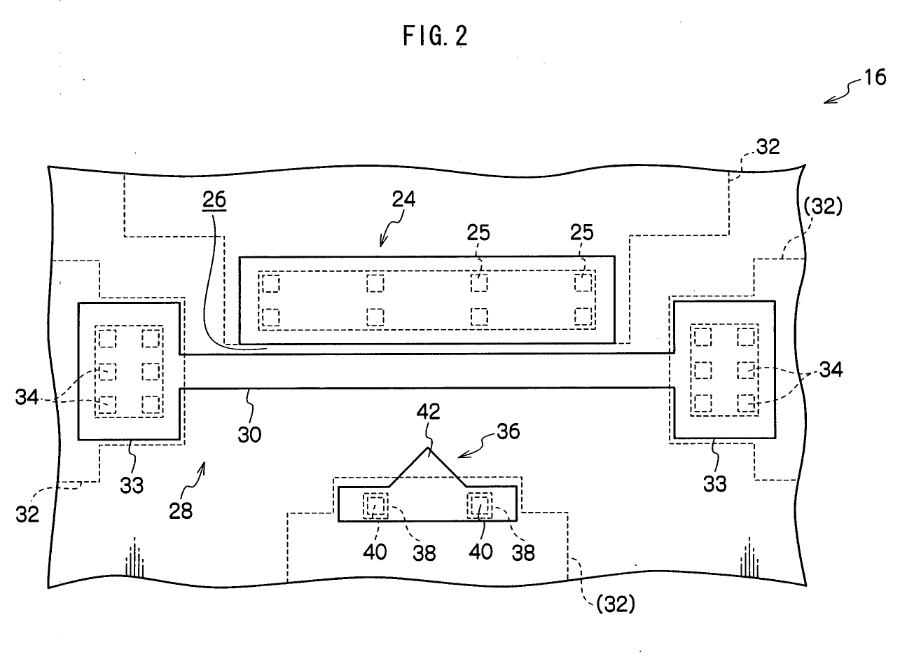

As shown in FIG. 1, the MEMS oscillator 16 is provided with a semiconductor substrate 20 formed from an Si wafer or the like, and a fixed electrode 24 having a rectangular parallelepiped shape is disposed on the semiconductor substrate 20 via an insulating film 22. A wiring layer 32 is provided below the fixed electrode 24 via the insulating film 22 and the fixed electrode 24 and the wiring layer 32 are electrically connected via plural contact portions 25 (See FIG. 2) extending from the bottom surface of the fixed electrode 24. Further, a vibration element 28 is disposed such that a gap 26 exists between the fixed electrode 24 and the vibration element 28.

As shown in FIG. 1 and FIG. 2, a beam portion 30, which is formed in a rectangular parallelepiped shape and may be vibrated, is provided in the vibration element 28. Further, the beam portion 30 is supported by beam fixing portions 33 provided at both ends of the beam portion 30 and projecting from the insulating film 22. Moreover, the beam fixing portions 33 and the wiring layer 32 are electrically connected via plural contact portions 34 extending from the undersurface of the beam fixing portions 33.

With this configuration, an electrostatic force is generated between the fixed electrode 24 and the beam portion 30 of the vibration element 28 by applying a predetermined voltage to the fixed electrode 24 and the vibration element 28 via the wiring layer 32, causing the beam portion 30 to vibrate.

A discharge electrode 36, which can discharge, is provided on the opposite side of the fixed electrode 24 with the beam portion 30 being sandwiched therebetween. Two legs 38 projecting from the insulating film 22 are provided in the discharge electrode 36 and the discharge electrode 36 and the wiring layer 32 are electrically connected via contact portions 40 extended from the undersurface of the legs 38.

Further, the discharge electrode 36 has a projection portion 42 tapering off toward the beam portion 30 provided thereon so as to make an arc discharge more likely to occur. This is intended to make a discharge more likely occur by concentrating an electric field on the tapering tip portion. In the exemplary embodiment, the distance between the beam portion 30 and the projection portion 42 of the discharge electrode 36 is set at 2 μm.

Further, both of the vibration element 28 and the discharge electrode 36 are constituted by the same element or formed from materials containing the same element. That is, the material of the discharge electrode 36 is selected so that the material has excellent adhesion properties with the vibration element 28. In the exemplary embodiment, as an example, a silicon material is used as a molding material of the discharge electrode 36 and the vibration element 28.

As shown in FIG. 3, on the other hand, the oscillation chamber 14 shut down from the outside by the sealing cap 12 is, as described above, in an approximate vacuum and further contains an inert gas.

Since the vibration element 28 is formed from a silicon material in the exemplary embodiment, for example, one of helium (He), neon (Ne), argon (Ar), krypton (Kr), and xenon (Xe) or two or more of these gases may be used as composition of the inert gas.

(Operation Effect)

If, with the above configuration, the frequency of the MEMS oscillator 16 is regulated by increasing the mass of the vibration element 28, the vibration element 28 is used as a positive electrode and the discharge electrode 36 is used as a negative electrode, and a direct current voltage is applied until an arc discharge occurs. Under the present circumstances, an instantaneous high voltage may be applied to start an arc discharge if necessary.

When an arc discharge occurs between the vibration element 28 and the discharge electrode 36, an inert gas contained in the oscillation chamber 14 is ionized to form positive ions. Accordingly, the positive ions collide against the discharge electrode 36, which functions as a negative electrode, to sputter or evaporate the material constituting the discharge electrode 36. Then, a portion of the material discharged from the discharge electrode 36 adheres to the vibration element 28.

In this manner, a portion of the discharged material may be made to adhere to the vibration element 28 to increase the mass of the vibration element 28 so that the resonance frequency of the MEMS oscillator 16 may be reduced.

Here, if the amount of change of resonance frequency per unit of time under the discharge conditions that are employed is determined in advance, the amount of regulation of the resonance frequency may be controlled according to the discharge duration.

On the other hand, when the frequency of the MEMS oscillator 16 is regulated by decreasing the mass of the vibration element 28, the vibration element 28 is used as a negative electrode and the discharge electrode 36 is used as a positive electrode, and a direct current voltage is applied until an arc discharge occurs. Under the circumstances, an instantaneous high voltage may be applied to start an arc discharge if necessary.

When an arc discharge occurs between the vibration element 28 and the discharge electrode 36, an inert gas contained in the oscillation chamber 14 is ionized to become positive ions. Thus, the positive ions collide against the vibration element 28 used as a negative electrode to sputter or evaporate the material constituting the vibration element 28.

Since a portion of the material of the vibration element 28 being discharged in this manner, the mass of the vibration element 28 may be decreased to increase the resonance frequency.

If the amount of change of resonance frequency per unit time under discharge conditions to be used is determined in advance, the amount of regulation of the resonance frequency may be controlled by the discharge duration.

The procedure for regulating the frequency of the MEMS oscillator 16 will be described below.

First, a case in which the resonance frequency of the vibration element 28 is higher than a target frequency will be described.

At step 1, the frequency of the vibration element 28 before regulation is measured.

At step 2, an arc discharge is caused by using the vibration element 28 as a positive electrode and the discharge electrode 36 as a negative electrode.

At step 3, a difference between the resonance frequency and the target frequency is determined and the arc discharge duration is controlled to fit the resonance frequency to the target frequency.

At step 4, the frequency of the vibration element 28 after regulation is measured.

The step 2 and steps thereafter will be repeated until the oscillating frequency is obtained with a necessary precision.

Next, a case in which the resonance frequency of the vibration element 28 is lower than a target frequency will be described.

At step 11, the frequency of the vibration element 28 before regulation is measured.

At step 12, an arc discharge is caused by using the vibration element 28 as a negative electrode and the discharge electrode 36 as a positive electrode.

At step 13, a difference between the resonance frequency and the target frequency is checked and the arc discharge duration is controlled to fit the resonance frequency to the target frequency.

At step 14, the frequency of the vibration element 28 after regulation is measured.

The step 12 and steps thereafter will be repeated until the oscillating frequency is obtained with a necessary precision.

In this manner, the resonance frequency of the vibration element 28 may be regulated by measuring the frequency and applying the voltage to cause an arc discharge after the MEMS oscillator 16 being assembled. Therefore, the frequency of the MEMS oscillator 16 may be easily regulated.

Further, the need for selecting a MEMS oscillator of the target frequency from plural MEMS oscillators of different frequencies may be eliminated so that the installation area may be saved.

Further, there is no need for regulation using a special vacuum device such as regulation of the resonance frequency of a crystal resonator so that time and efforts may be saved.

Further, the frequency may be regulated regardless of whether the resonance frequency of the vibration element 28 is higher or lower than the desired frequency.

Further, by selecting a silicon material as a molding material of both the discharge electrode 36 and the vibration element 28, i.e., by forming both the discharge electrode 36 and the vibration element 28 from the same material, material evaporated from the discharge electrode 36 may be easily adhered to the vibration element 28.

Incidentally, the present invention provides a resonance frequency regulation method using an arc discharge occurring between the vibration element 28 and the discharge electrode 36, and if the vibration element and the discharge electrode are sufficiently apart from each other, plasma may be generated between the vibration element and the discharge electrode to use ions obtained by ionizing a gas by plasma.

The exemplary embodiment is described as a case in which a lid is used when the MEMS oscillator 16 is mounted in a package as a cover structure, but the invention may similarly be applicable to other methods of sealing in a vacuum. For example, the invention may also be applied to a method of vacuum sealing by a processed Si wafer and a method of vacuum sealing by a wafer process.

### Second Exemplary Embodiment

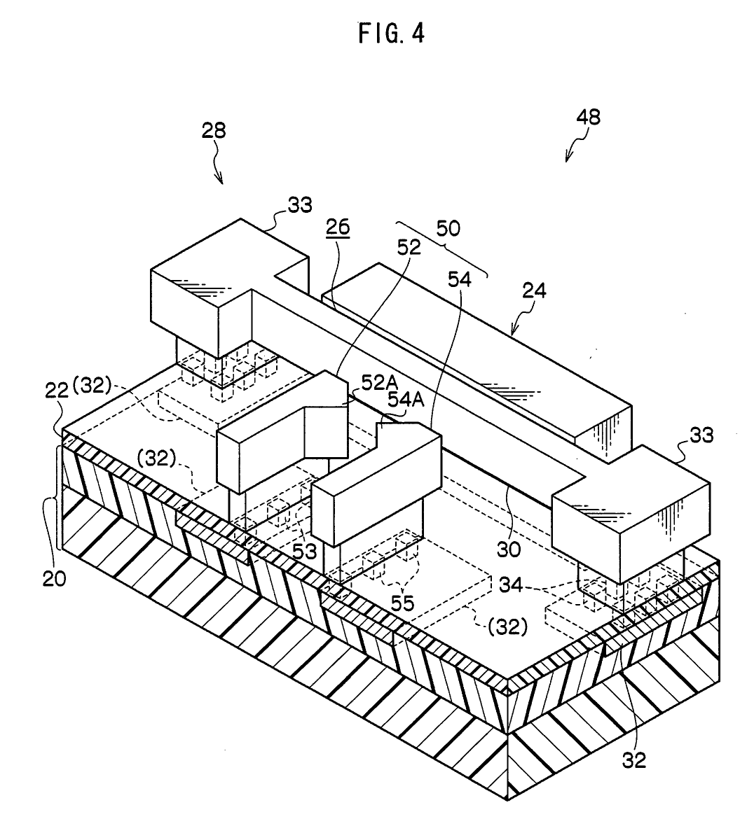

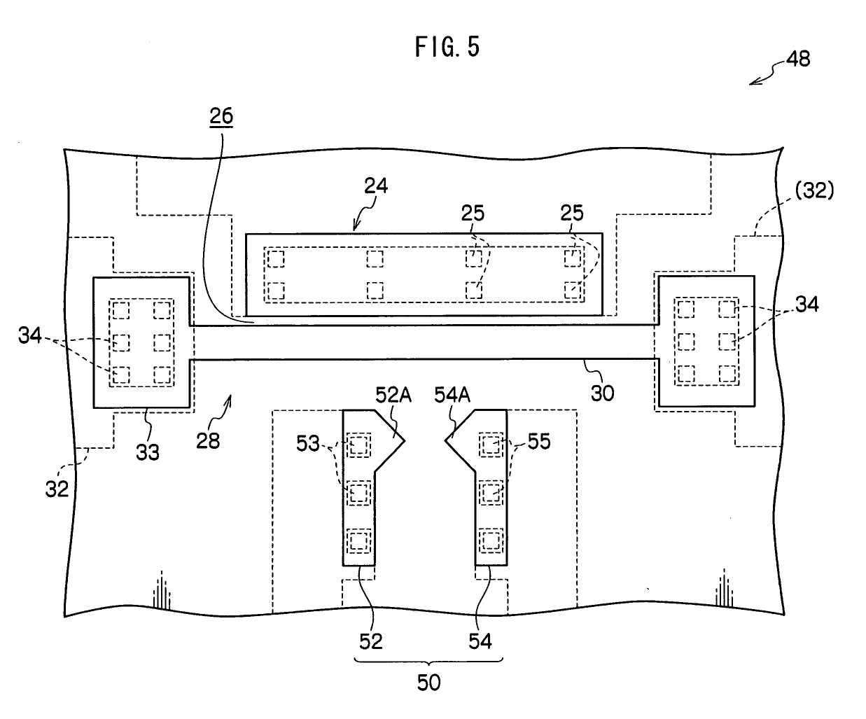

Next, an example of a MEMS oscillator 48 according to the second exemplary embodiment of the invention will be described by referring to FIG. 4 and FIG. 5.

The same reference numerals are assigned to the same members as those in the first exemplary embodiment and a description thereof is omitted.

In contrast to the first exemplary embodiment, as shown in FIG. 4 and FIG. 5, a pair of dischargable discharge electrodes 50 is provided in the exemplary embodiment on the opposite side of the fixed electrode 24 with the beam portion 30 being sandwiched therebetween.

The pair of discharge electrodes 50 is provided with a discharge electrode 52 and a discharge electrode 54 facing each other, and the tapering projection portions 52A and 54A are provided on the discharge electrodes 52 and 54, respectively, to make an arc discharge more likely to occur. This is intended to make a discharge more likely occur by concentrating an electric field on the tapering tip portion. Further, the discharge electrodes 52 and 54 are connected to the wiring layer 32 via contact portions 53 and 55, respectively. In the exemplary embodiment, the inter-electrode distance between the discharge electrode 52 and the discharge electrode 54 is set at 2 μm, and the distance between the vibration element 28 and the discharge electrodes 50 is set at 1 μm.

With the above configuration, the resonance frequency of the MEMS oscillator 48 may be regulated by increasing the mass of the vibration element 28.

More specifically, a direct current voltage is applied until an arc discharge occurs by using one discharge electrode, the discharge electrode 52, as a positive electrode and the other discharge electrode, the discharge electrode 54, as a negative electrode. Under the present circumstances, an instantaneous high voltage may be applied to start an arc discharge if necessary.

When an arc discharge occurs, an inert gas contained in the oscillation chamber 14 is ionized to become positive ions. Thus, the positive ions collide against the discharge electrode 54 used as a negative electrode to sputter or evaporate the material constituting the discharge electrode 54. Then, a portion of the material discharged from the discharge electrode 54 adheres to the vibration element 28. Accordingly, the mass of the vibration element 28 may be increased to reduce the resonance frequency.

If the amount of change of resonance frequency per unit time under discharge conditions to be used is determined in advance, the amount of regulation of the resonance frequency may be controlled by the discharge duration.

The procedure for regulating the frequency of the MEMS oscillator 48 will be described below.

First, a MEMS oscillator is produced so that the frequency of the MEMS oscillator before regulation is higher than a target value.

At step 21, the frequency of the MEMS oscillator 48 before regulation is measured.

At step 22, an arc discharge is caused by using the discharge electrode 54 as a negative electrode and the discharge electrode 54 as a positive electrode.

At step 23, a difference between the resonance frequency and the target frequency is checked and the arc discharge duration is controlled to fit the resonance frequency to the target frequency.

At step 24, the frequency of the MEMS oscillator 48 after regulation is measured.

The step 22 and steps thereafter will be repeated until the oscillating frequency is obtained with a necessary precision.

Thus, a discharge is caused between the discharge electrode 52 and the discharge electrode 54 in this manner and, therefore, the need for applying a discharge voltage to the vibration element 28 is eliminated, resulting in reduction of discharge damage received by the vibration element 28.

Further, a discharge distance between the discharge electrode 52 and the discharge electrode 54 may be set to be shorter so that an arc discharge may be caused at lower voltage.

Incidentally, the invention provides a resonance frequency regulation method using an arc discharge between a pair of discharge electrodes, and if the discharge distance between the discharge electrodes is sufficient, plasma may be generated therebetween to use ions obtained by ionizing a gas by plasma.

### Third Exemplary Embodiment

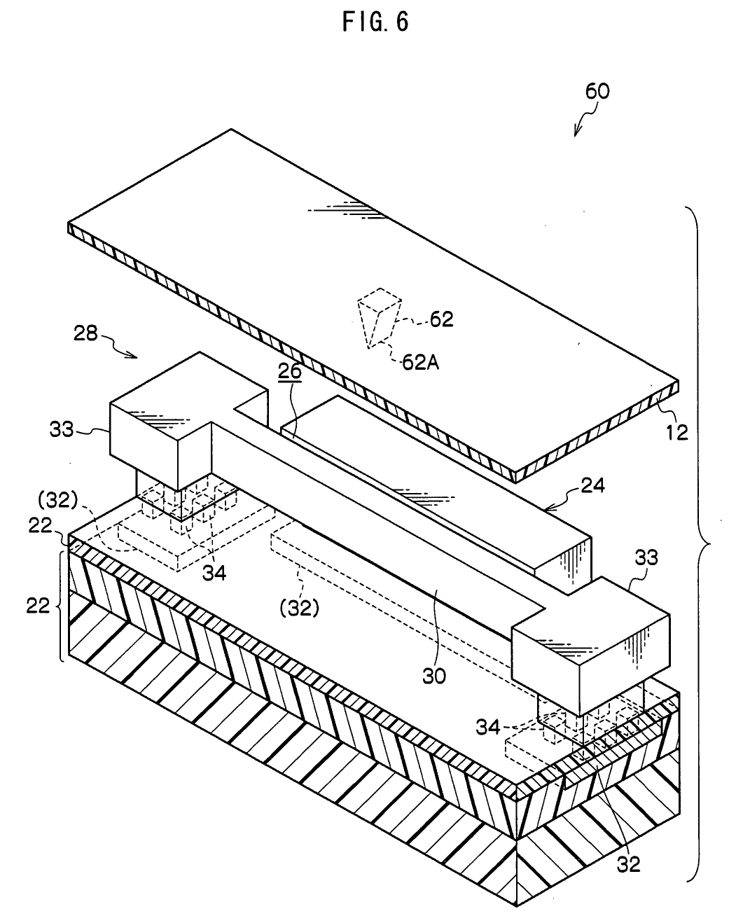

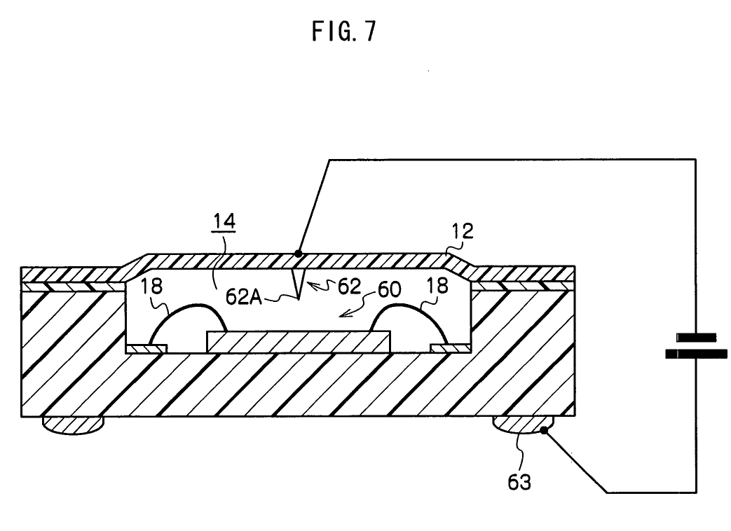

Next, an example of a MEMS oscillator 60 according to the third exemplary embodiment of the invention will be described by referring to FIG. 6 and FIG. 7.

The same reference numerals are assigned to the same members as those in the first exemplary embodiment and a description thereof is omitted.

In contrast to the first exemplary embodiment, as shown in FIG. 6 and FIG. 7, no discharge electrode is provided in the present exemplary embodiment on the opposite side of the fixed electrode 24 with the beam portion 30 being sandwiched therebetween and instead, a discharge electrode 62 is provided on the sealing cap 12 opposite to the beam portion 30.

More specifically, the sealing cap 12 is formed from a conductive material and the discharge electrode 62 is fixed to the inside surface of the sealing cap 12. The discharge electrode 62 has a tapering projection portion 62A toward the beam portion 30 provided thereon so as to make an arc discharge more likely to occur. This is intended to make a discharge more likely occur by concentrating an electric field on the tapering tip portion. In the exemplary embodiment, the distance between the beam portion 30 and the projection portion 62A of the discharge electrode 62 is set at 10 μm.

In the case of which the discharge electrode 62 is used as a positive electrode, the discharge electrode 62 need not necessarily have a structure to concentrate an electric field (a structure having a tapered tip) and may have a flat shape.

With this configuration, the resonance frequency may be regulated to the target frequency regardless of whether the resonance frequency of the MEMS oscillator 60 is higher or lower than the target frequency.

Since the discharge electrode 62 is connected to the conductive sealing cap 12, an external power source for arc discharge may be easily connected at the time of regulation, as shown in FIG. 7.

### Fourth Exemplary Embodiment

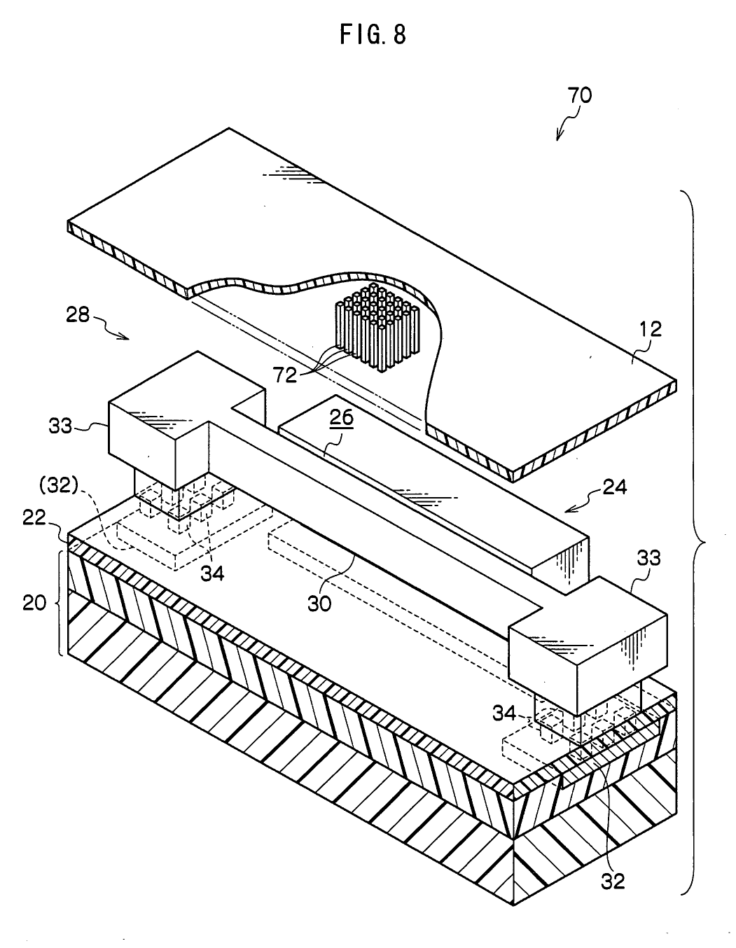

Next, an example of a MEMS oscillator 70 according to the fourth exemplary embodiment of the invention will be described by referring to FIG. 8.

The same reference numerals are assigned to the same members as those in the third exemplary embodiment and a description thereof is omitted.

In contrast to the third exemplary embodiment, as shown in FIG. 8, plural rod discharge electrodes 72 are provided in the exemplary embodiment from the sealing cap 12 toward the vibration element 28.

By providing plural rod discharge electrodes 72 in this manner, the need for a high precision for positioning of the discharge electrodes 72 and the vibration element 28 is eliminated.

### Fifth Exemplary Embodiment

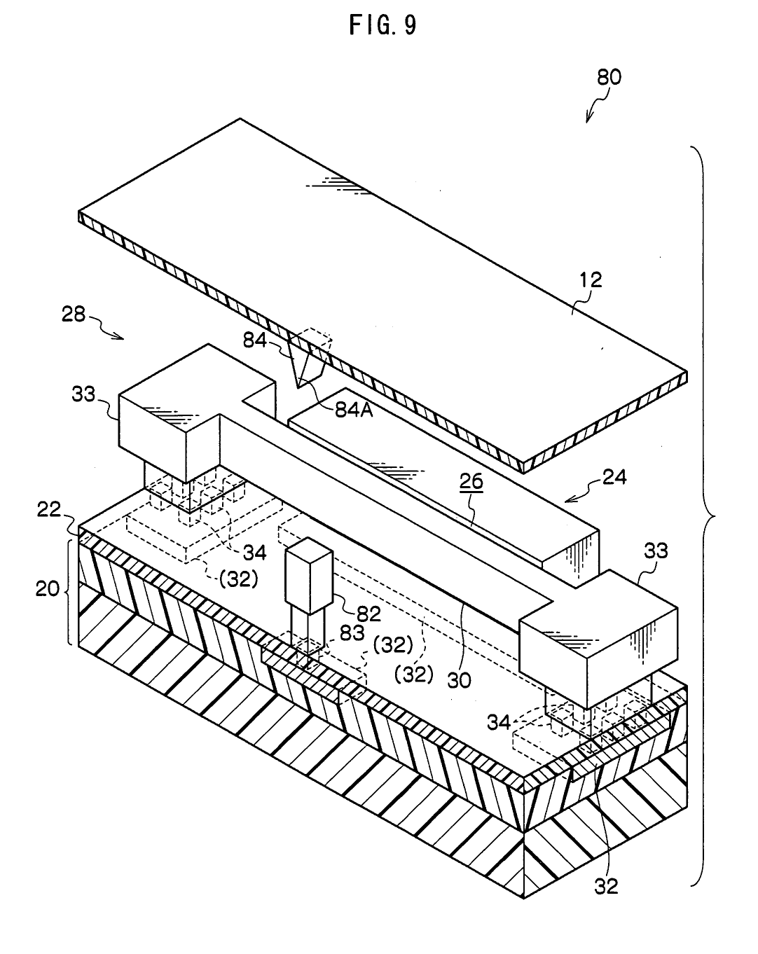

Next, an example of a MEMS oscillator 80 according to the fifth exemplary embodiment of the invention will be described by referring to FIG. 9.

The same reference numerals are assigned to the same members as those in the first exemplary embodiment and a description thereof is omitted.

In contrast to the first exemplary embodiment, as shown in FIG. 9, a discharge electrode 82 in a rectangular parallelepiped shape having no projection portion is provided in the present exemplary embodiment on the opposite side of the fixed electrode 24 with the beam portion 30 being sandwiched therebetween.

Further, the conductive sealing cap 12 has a discharge electrode 84 provided thereon opposite to the discharge electrode 82. The discharge electrode 84 has a tapering projection portion 84A toward the discharge electrode 82 provided thereon so as to make an arc discharge more likely to occur. This is intended to make a discharge more likely occur by concentrating an electric field on the tapering tip portion. In the exemplary embodiment, the distance between the discharge electrode 82 and the projection portion 84A of the discharge electrode 82 is set at 10 μm. If the discharge electrode 84 is used as a positive electrode, the discharge electrode 84 need not necessarily have a structure to concentrate an electric field (a structure having a tapered tip) and may have a flat shape.

Further, the discharge electrode 82 and the discharge electrode 84 are formed from the same material as that of the vibration element 28 or formed from materials containing the same element. That is, the material of the discharge electrode 82 and the discharge electrode 84 is selected so that the material has excellent adhesion properties with the vibration element 28.

In the exemplary embodiment, the molding material of the discharge electrode 82, the discharge electrode 84, and the vibration element 28 is silicon.

With the above configuration, the resonance frequency of the MEMS oscillator 80 may be regulated by increasing the mass of the vibration element 28.

More specifically, a direct current voltage is applied until an arc discharge occurs by using the discharge electrode 84 as a positive electrode and the discharge electrode 82 as a negative electrode. Under the present circumstances, an instantaneous high voltage may be applied to start an arc discharge if necessary.

When an arc discharge occurs, an inert gas contained in the oscillation chamber 14 is ionized to become positive ions. Thus, the positive ions collide against the discharge electrode 82 used as a negative electrode to sputter or evaporate the material constituting the discharge electrode 82. Then, a portion of the material discharged from the discharge electrode 82 adheres to the vibration element 28. Accordingly, the mass of the vibration element 28 may be increased to reduce the resonance frequency.

If the amount of change of resonance frequency per unit time under discharge conditions to be used is determined in advance, the amount of regulation of the resonance frequency may be controlled by the discharge duration.

The procedure for regulating the frequency of the MEMS oscillator 80 will be described below.

First, a MEMS oscillator is produced so that the frequency of the MEMS oscillator before regulation is higher than a target value.

At step 31, the frequency of the MEMS oscillator 80 before regulation is measured.

At step 32, an arc discharge is caused by using the discharge electrode 82 as a negative electrode and the discharge electrode 84 as a positive electrode.

At step 33, a difference between the resonance frequency and the target frequency is checked and the arc discharge duration is controlled to fit the resonance frequency to the target frequency.

At step 34, the frequency of the MEMS oscillator 80 after regulation is measured.

The step 32 and steps thereafter will be repeated until the oscillating frequency is obtained with a necessary precision.

Thus, a discharge is caused between the discharge electrode 82 and the discharge electrode 84 in this manner and therefore, the need for applying a discharge voltage to the vibration element 28 is eliminated, resulting in reduction of discharge damage received by the vibration element 28.

Further, the discharge distance between the discharge electrode 82 and the discharge electrode 84 may be set to be shorter so that an arc discharge may be caused at lower voltage.

### Sixth Exemplary Embodiment

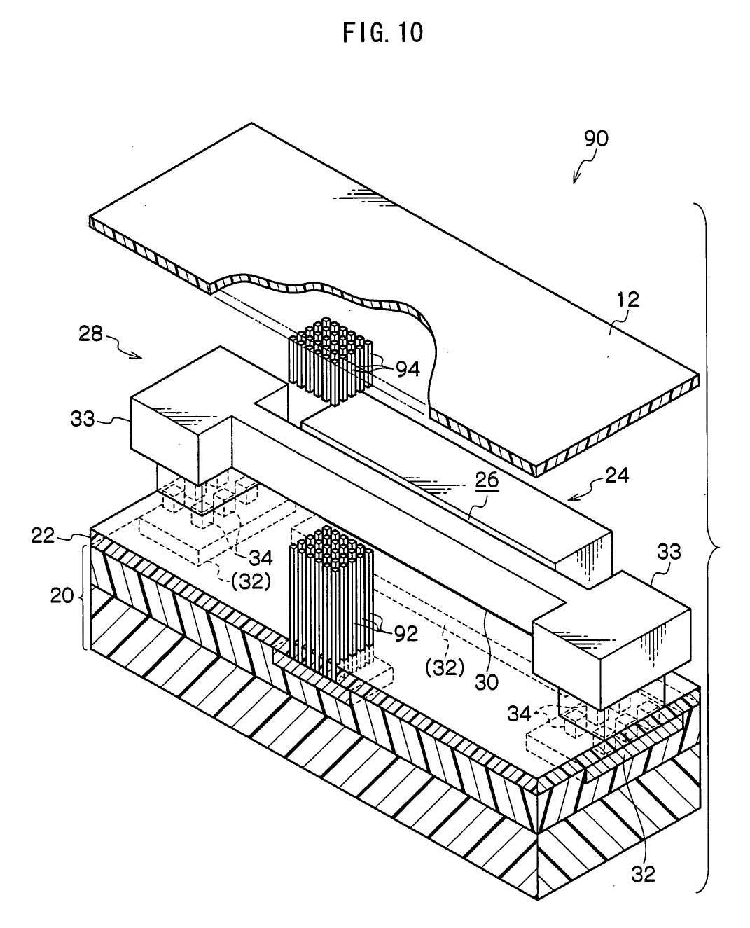

Next, an example of a MEMS oscillator 90 according to the sixth exemplary embodiment of the invention will be described by referring to FIG. 10.

The same reference numerals are assigned to the same members as those in the fifth exemplary embodiment and a description thereof is omitted.

In contrast to the fifth exemplary embodiment, as shown in FIG. 10, a discharge electrode 92 and a discharge electrode 94 each consist of plural rod electrodes.

By providing plural discharge electrodes 92 and discharge electrode 94 in this manner, the need for a high precision for positioning of the discharge electrodes 92 and the discharge electrodes 94 are eliminated.

What is claimed is:

1. A MEMS oscillator, comprising:
a vibration element disposed in opposition to a fixed electrode provided on a substrate; and
a discharge portion provided adjacent to the vibration element.

2. The MEMS oscillator of claim 1, wherein the vibration element and the discharge portion are disposed inside a sealed oscillation chamber and an inert gas is contained in the oscillation chamber.

3. The MEMS oscillator of claim 2, wherein the inert gas is at least one of helium, neon, argon, krypton, or xenon.

4. The MEMS oscillator of claim 1, wherein a material of the vibration element and a material of the discharge portion are identical or comprise a common material.

5. The MEMS oscillator of claim 1, wherein the discharge portion comprises a single discharge electrode.

6. The MEMS oscillator of claim 1, wherein the discharge portion comprises a pair of discharge electrodes.

7. A MEMS oscillator, comprising:
a semiconductor substrate;
an insulating film formed on the semiconductor substrate;
a fixed electrode having a substantially rectangular parallelepiped shape disposed on the insulating film;
a vibration element disposed such that a gap is interposed between the fixed electrode and the vibration element; and
a discharge portion provided adjacent to the vibration element.

8. The MEMS oscillator of claim 7, wherein a beam portion having a rectangular parallelepiped shape and being configured to vibrate is provided at the vibration element.

9. The MEMS oscillator of claim 8, wherein the discharge portion comprises a discharge electrode provided on the opposite side of the beam portion to the fixed electrode with the beam portion interposed therebetween.

10. The MEMS oscillator of claim 9, wherein a projection portion tapering off toward the beam portion is provided at the discharge electrode.
